(19) United States
(12) Patent Application Publication
(10) Pub. No.: US 2023/0253506 A1
(43) Pub. Date: Aug. 10, 2023

(54) SEMICONDUCTOR DEVICE AND DISPLAY DEVICE

(71) Applicant: Japan Display Inc., Tokyo (JP)

(72) Inventors: Ryo ONODERA, Tokyo (JP); Akihiro HANADA, Tokyo (JP); Takuo KAITOH, Tokyo (JP); Tomoyuki ITO, Tokyo (JP)

(73) Assignee: Japan Display Inc., Tokyo (JP)

(21) Appl. No.: 18/163,286

(22) Filed: Feb. 2, 2023

(30) Foreign Application Priority Data
Feb. 4, 2022 (JP) 2022-016479

(51) Int. Cl. H01L 29/786; G02F 1/1362; G02F 1/1368

(52) U.S. Cl. CPC H01L 29/7869; G02F 1/136286; G02F 1/1368

(57) ABSTRACT

According to one embodiment, a semiconductor device includes a first gate electrode formed to be integrated with a scanning line, an oxide semiconductor layer, a first signal line and a second signal line in contact with the oxide semiconductor layer, and a second gate electrode disposed opposing the first gate electrode with the oxide semiconductor layer interposed therebetween, and connected to the first gate electrode, wherein the second gate electrode does not overlap the first signal line, but overlaps the second signal line.

### CROSS-REFERENCE TO RELATED APPLICATIONS

This application is based upon and claims the benefit of priority from Japanese Patent Application No. 2022-016479, filed Feb. 4, 2022, the entire contents of which are incorporated herein by reference.

### FIELD

Embodiments described herein relate generally to a semiconductor device and a display device.

### BACKGROUND

In the field of display devices, such a technology has been developed in which a transistor comprising an oxide semiconductor is installed in pixel circuits of the display area.

### BRIEF DESCRIPTION OF THE DRAWINGS

FIG. 1 an exploded perspective view of an example of a schematic configuration of a display device of Embodiment 1.

FIG. 2 is a cross-sectional view of a configuration example of a transistor according to a comparative example.

FIG. 3 is a plan view of the transistor shown in FIG. 2.

FIG. 4 is a cross-sectional view of a schematic configuration example of the transistor according to Embodiment 1.

FIG. 5 is a plan view of the transistor shown in FIG. 4.

FIG. 6 is a plan view of a schematic configuration example of a transistor including a single oxide semiconductor layer.

FIG. 7 is a circuit diagram showing a schematic configuration of a transistor.

FIG. 8 is a plan view showing a configuration example of a transistor in Embodiment 2.

FIG. 9 is a cross-sectional view of the transistor taken along line C1-C2 shown in FIG. 8.

### DETAILED DESCRIPTION

In general, according to one embodiment, a semiconductor device comprises a first gate electrode formed to be integrated with a scanning line; an oxide semiconductor layer; a first signal line and a second signal line in contact with the oxide semiconductor layer; and a second gate electrode disposed opposing the first gate electrode with the oxide semiconductor layer interposed therebetween, and connected to the first gate electrode, wherein the second gate electrode does not overlap the first signal line, but overlaps the second signal line.

According to another embodiment, a semiconductor device comprises a first gate electrode formed to be integrated with a scanning line; an oxide semiconductor layer; a first signal line and a second signal line in contact with the oxide semiconductor layer; and a second gate electrode disposed to oppose the first gate electrode with the oxide semiconductor layer interposed therebetween, and connected to the first gate electrode, wherein the second gate electrode overlaps a part of the first signal line in a width direction of the first signal line and does not overlap any other part of the first signal line, the second gate electrode overlaps the second signal line.

An object of the embodiments is to provide a semiconductor device in which the occurrence of electrostatic discharge errors is suppressed, and a display device in which lowering of aperture ratio can be prevented.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general, but rather embodiments that illustrate the same or corresponding special technical features of the invention. The following is a detailed description of a display device according to one embodiment with reference to the drawings.

In the embodiments, a first direction X, a second direction Y and a third direction Z are orthogonal to each other, but may intersect at an angle other than 90 degrees. In the following descriptions, a direction towards a tip side of an arrow in the third direction Z is defined as above or upwards, and a direction opposite to the direction towards the tip side of an arrow in the third direction Z is defined as below or downwards. Note that the first direction X, the second direction Y and the third direction Z may as well be referred to as an X direction, a Y direction and a Z direction, respectively.

With such expressions “a second member above a first member” and “a second member below a first member”, the second member may be in contact with the first member or may be remote from the first member. In the latter case, a third member may be interposed between the first member and the second member. On the other hand, when “the second member on the first member” and “the second member underneath the first member”, the second member is in contact with the first member.

Further, it is assumed that there is an observation position to observe the display device on the side of the tip of the arrow in the third direction Z. Here, viewing from this observation position toward an X-Y plane defined by the first direction X and the second direction Y is referred to as plan view. Viewing the cross-section of the display device in an X-Z plane defined by the first direction X and the third direction Z or in a Y-Z plane defined by the second direction Y and the third direction Z is referred to as cross-sectional view.

### Embodiment 1

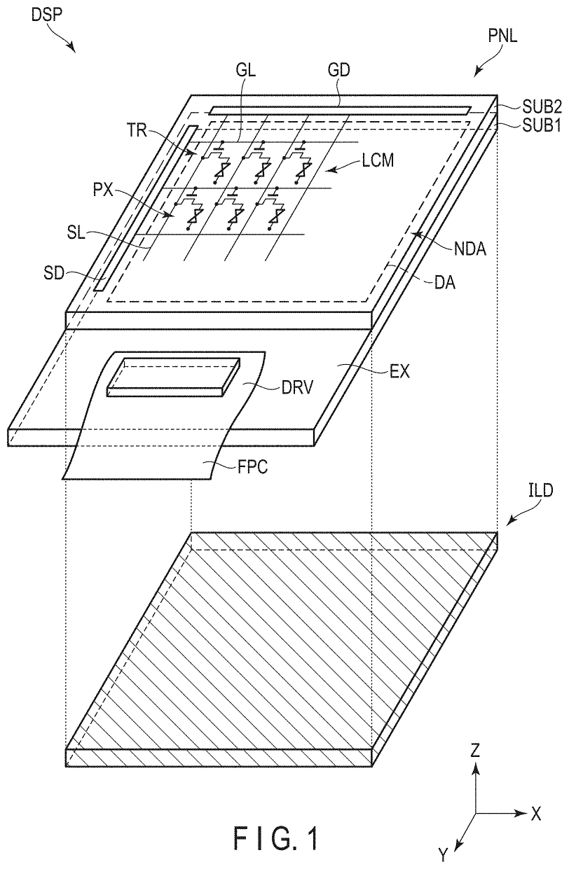

FIG. 1 is an exploded perspective view showing an example of a schematic configuration of a display device of this embodiment. The display device DSP comprises an illumination device ILD and a display panel PNL.

The illumination device ILD may comprise a plurality of light source elements, a light guide and an optical sheet, which are not shown in the figure. The illumination device ILD may be of the so-called direct type or sidelight type.

The display panel PNL comprises a substrate SUB1, a substrate SUB2 and a liquid crystal layer (not shown) sandwiched between the substrates SUB1 and SUB2. In the area where substrates SUB1 and SUB2 overlap each other, a display area DA and a non-display area NDA are provided. The display area DA includes a plurality of pixels PX, a plurality of signal lines SL(, which may as well be referred to as source lines), and a plurality of scanning lines GL(, which may as well be referred to as gate lines). The pixels PX are each provided at an intersection of each signal line SL and each respective scanning line GL. In the non-display area NDA, a signal line driving circuit SD(, which may as well be referred to as a source driver) connected to the signal lines SL and a scanning line driving circuit GD(, which may as well be referred to as a gate driver) connected to the scanning lines GL are provided.

Each of the pixels PX includes a transistor TR and a liquid crystal element LCM.

The region of the substrate SUB1, which does not overlap the substrate SUB2 is an end portion EX. In the end portion EX, a flexible wiring board FPC which is connected to the signal lines SL and the scanning lines GL, and a drive element DRV are provided. The drive element DRV is electrically connected to the signal lines SL and the scanning lines GL via the flexible wiring board FPC, and drive signals are input thereto.

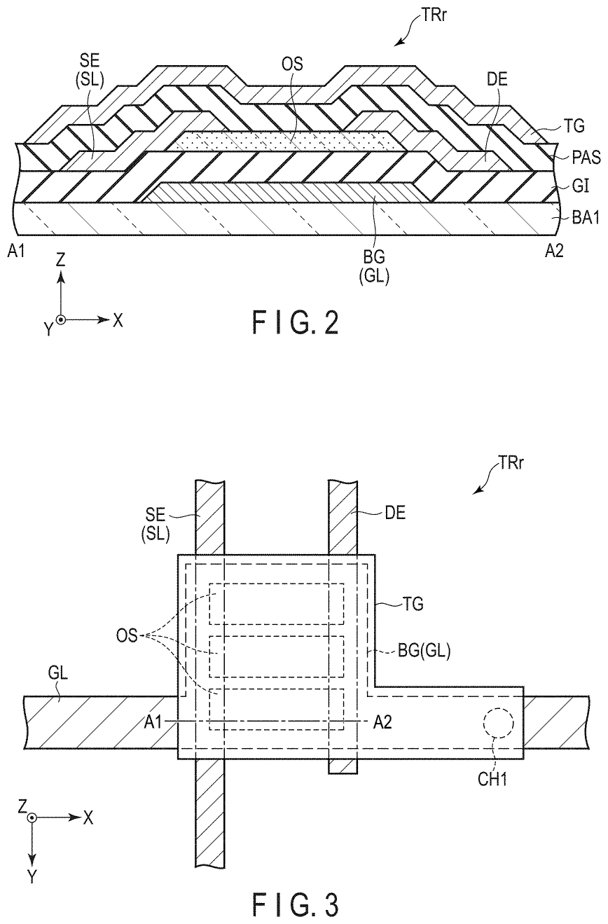

FIG. 2 is a cross-sectional view showing an example of the schematic configuration of a transistor according to a comparative example. FIG. 3 is a plan view of the transistor shown in FIG. 2. FIG. 2 is a cross-sectional view of the transistor taken along the line A1-A2 shown in FIG. 3.

A transistor TRr is provided on a base BA1. The transistor TRr comprises a gate electrode BG, an oxide semiconductor layer OS, an insulating layer GI, a source electrode SE, a drain electrode DE, an insulating layer PAS and a gate electrode TG. The gate electrode BG and the gate electrode TG are referred as well to as a bottom gate and a top gate, respectively. Or, the gate electrode BG and the gate electrode TG may as well be referred to as a first gate electrode and a second gate electrode, respectively. Between the base BA1 and the gate electrode BG, an insulating layer may be provided.

The material of the base BA1 is glass or resin. Examples of such a resin are polyimide resin and acrylic resin.

It suffices if the gate electrode BG is formed, for example, of a metal material or a metal material of a single metal film or a stacked multilayered film of multiple metal films. Specific examples thereof include a molybdenum-tungsten alloy (MoW) film and a stacked multilayer film in which an aluminum alloy film is sandwiched between titanium films. Note that the gate electrode BG is formed to be integrated with the scanning lines GL.

The insulating layer GI is provided to cover the gate electrode BG and the base BA1. The insulating layer GI is formed, for example, of a single layer of silicon oxide or silicon nitride or a multilayer thereof. As the insulating layer GI, an inorganic material containing oxygen, for example, silicon oxide is more suitable. The insulating layer GI may have the function of blocking impurities from glass and the like.

The oxide semiconductor layer OS is provided above the gate electrode BG while interposing the insulating layer GI therebetween. The oxide semiconductor layer OS is formed using indium gallium zinc oxide (IGZO), indium tin zinc oxide (ITZO), zinc oxide nitride (ZnON), indium gallium oxide (IGO) or the like. It can be said that the transistor TRr is a semiconductor device in which the oxide semiconductor layer OS is an active layer.

On the insulating layer GI, a source electrode SE and a drain electrode DE are provided. The source electrode SE and drain electrode DE are each in direct contact with the oxide semiconductor layer OS. The areas of the oxide semiconductor layer OS, which are in contact with the source electrode SE and the drain electrode DE are referred to as a source region and a drain region, respectively. The source electrode SE and the drain electrode DE are each formed, for example, from a multilayer film (of titanium/aluminum/titanium (Ti/Al/Ti)) in which an aluminum alloy layer is sandwiched by titanium films. The source electrode SE is formed to be integrated with the signal line SL. Not that the signal line SL and the source electrode SE may each be referred to as a first signal line in general, and the drain electrode DE as a second signal line.

An insulating layer PAS is provided to cover the insulating layer GI, the oxide semiconductor layer OS, the source electrode SE and the drain electrode DE. It suffices if the insulating layer PAS is formed using the same material as that of the insulating layer GI.

On the insulating layer PAS, a gate electrode TG is provided so as to oppose the oxide semiconductor layer OS. If suffices if the gate electrode TG is formed using a light-shielding conductive metal material, for example, a single layer metal film or a multilayer film of multiple metal films. Specific examples thereof include a molybdenum-tungsten alloy (MoW) film or a multilayer film in which an aluminum alloy film is sandwiched between titanium films.

The oxide semiconductor layer OS is provided between the gate electrode BG and the gate electrode TG. It can be said that the gate electrode TG opposes the gate electrode BG while interposing the oxide semiconductor layer OS therebetween. The insulating layer PAS is provided between the gate electrode TG and the oxide semiconductor layer OS, and the insulating layer GI is provided between the gate electrode BG and the oxide semiconductor layer OS.

The gate electrode TG is connected to the scanning line GL (the gate electrode BG) via a contact hole CH1 provided in the insulating layer GI and the insulating layer PAS. In other words, the same gate voltage is applied to the gate electrode TG and the gate electrode BG.

When the gate electrode TG is provided in addition to the gate electrode BG, the transistor characteristics of the transistor TRr are stabilized. Further, the transistor TRr provided with the gate electrode BG and the gate electrode TG has an increased on-current. However, in regions where steps are created, such as regions which go over the signal line SL, the coverage property of the insulation layer becomes poor, and electro-static discharge (ESD) errors may undesirably increase.

Further, if the source electrode SE (signal line SL) and the gate electrode TG are disposed to be spaced apart from each other, the light-shielded area in the pixel PX may increase, resulting in a decrease in the aperture ratio.

In order to solve the problem of the ESD error, the signal line SL is not placed to overlap the gate electrode TG in the transistor of this embodiment. On the other hand, the drain electrode DE in this embodiment may overlap the gate electrode TG. The following is an explanation thereof using the drawings.

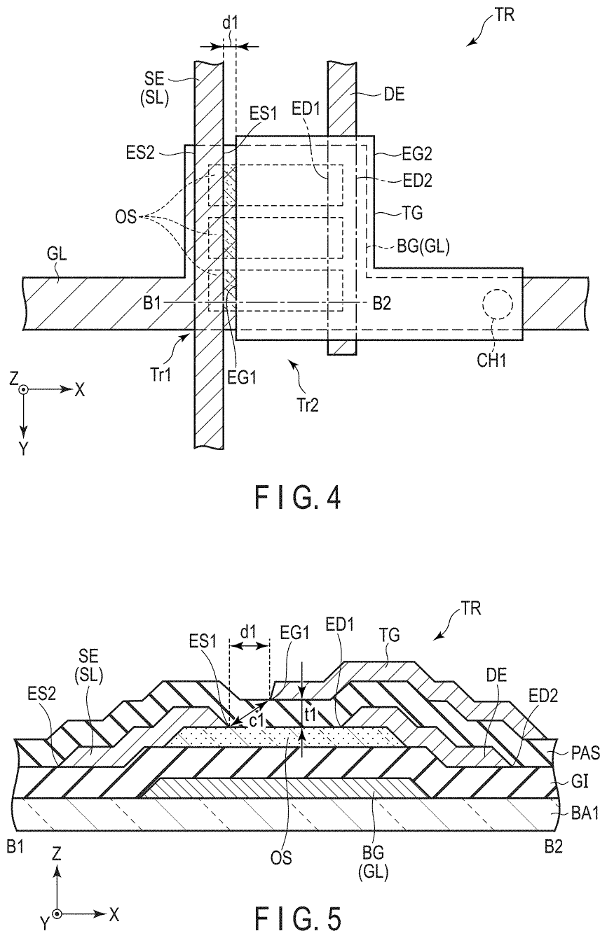

FIG. 4 is a cross-sectional view showing an example of the schematic configuration of the transistor in this embodiment. FIG. 5 is a plan view of the transistor shown in FIG. 4. FIG. 5 is a cross-sectional view of the transistor taken along line B1-B2 shown in FIG. 4.

The transistor TR shown in FIGS. 4 and 5 is different from the transistor TRr in the comparative example is the shape and arrangement of the gate electrode TG. The gate electrode TG of the transistor TR does not overlap the source electrode SE (signal line SL) in plan view. The gate electrode TG of the transistor TR overlaps the drain electrode DE in plan view.

Edge portions of the source electrode SE (signal line SL) and the drain electrode DE adjacent to the gate electrode TG are referred to as edge portions ES1 and ED1, respectively. The edge portion ES1 and the edge portion ED1 are adjacent to and oppose each other. The other edge of the source electrode SE, which opposes the edge portion ES1, is referred to as an edge portion ES2. The other edge of the drain electrode DE, which opposes the edge portion ED1 is referred to as an edge portion ED2. It can be said that the edges of the signal line SL, which extend along the second direction Y, are the edge portion ES1 and the edge portion ES2, respectively. Similarly, the edges of the drain electrode DE, which extend along the second direction Y may as well be the edge portion ED1 and the edge portion ED2, respectively.

The edges of the gate electrode TG adjacent to the source electrode SE and the drain electrode DE are referred to as an edge portion EG1 and an edge portion EG2, respectively. The edge portion EG1 is located between the edge portion ES1 and the edge portion ED1. The edge portion ED1 and the edge portion ED2 are located between the edge portion EG1 and the edge portion EG2. It can be said that the edges of the edge portions of the gate electrode TG, which extends along the second direction Y are the edge portion EG1 and the edge portion EG2. That is, the edge portion ES1, the edge portion ES2, the edge portion ED1, the edge portion ED2, the edge portion EG1, and the edge portion EG2 are edges of electrodes and wires as well extending along the second direction Y, and they are arranged parallel to each other.

Note that the edge portion ES1 and the edge portion ES2 of the source electrode SE (signal line SL), the edge portion ED1 and the edge portion ED2 of the drain electrode DE, and the edge portion EG1 and the edge portion EG2 of the gate electrode TG are referred as well to a first edge portion, a second edge portion, a third edge portion, a fourth edge portion, a fifth edge portion and a sixth edge portion, respectively.

The distance of the edge portion ES1 and the edge portion EG1 in plan view is referred to as a distance d1, the thickness of the insulating layer PAS is referred to as a film thickness t1, and the actual distance between the edge portion ES1 and the edge portion EG1 is referred to as a distance c1. When the distance c1 is short, there is a risk of short circuiting between the gate electrode TG and the signal line SL. Therefore, the distance c1 should preferably be 1000 nm or more. For example, if the film thickness t1 is 500 nm and the distance d1 is 866 nm or more, the distance c1 is 1000 nm or more.

The signal line SL is longer in wiring than the drain electrode DE. If the length of the wiring line is greater, there is a risk that charge is likely to accumulate. Further, there may be the case where the signal line SL is connected to an electric edge portion to which voltage from outside is applied. In such cases, high voltage from the outside is input to the signal line SL.

On the other hand, in the transistor TR of this embodiment, the drain electrode DE has an ESD resistance higher than that of the source electrode SE (signal line SL). To the drain electrode DE, no voltage is applied directly, but charge flows in via the oxide semiconductor layer OS. The transistor TR including the oxide semiconductor layer OS is a normally-off transistor. That is, when the transistor TR is in an off state, no charge flows to the drain electrode DE. Therefore, the possibility of high voltage being applied to the drain electrode DE side is low.

As described above, the source electrode SE, on which charge easily accumulates, which has low ESD resistance, is placed not to overlap the gate electrode TG. Thus, the creation of steps is suppressed, thereby making it possible to prevent ESD errors.

However, when the source electrode SE (signal line SL) and the gate electrode TG are disposed to be spaced apart from each other, the light-shielded area of the pixel PX increases and the aperture ratio may undesirably decrease.

In order to prevent the aperture ratio from decreasing, on the drain electrode DE side, where ESD errors are less likely to occur, the drain electrode DE and the gate electrode TG are placed to overlap each other. The transistor TR having such a configuration as discussed above suppresses ESD errors and does not cause a decrease in the aperture ratio. With the embodiment, it is possible to obtain a display device DSP with an improved yield rate and sufficient brightness.

The transistor TR shown in FIG. 4 includes three oxide semiconductor layers OS provided therein. The number of oxide semiconductor layers OS is not limited to this. Only one oxide semiconductor layer OS may be provided, or a plurality of, for example, two or more, may be provided. With plural oxide semiconductor layers OS provided, the transistor TR can obtain redundancy. Further, as the so-called channel width increases, the current resistance of the transistor TR increases. Note here that as the number of oxide semiconductor layers OS increases, the area occupied by the transistor TR increases, which may undesirably reduce the resolution. The number of oxide semiconductor layers OS should be determined appropriately in consideration of the resolution of the display device DSP, the stability of the transistor TR and the like.

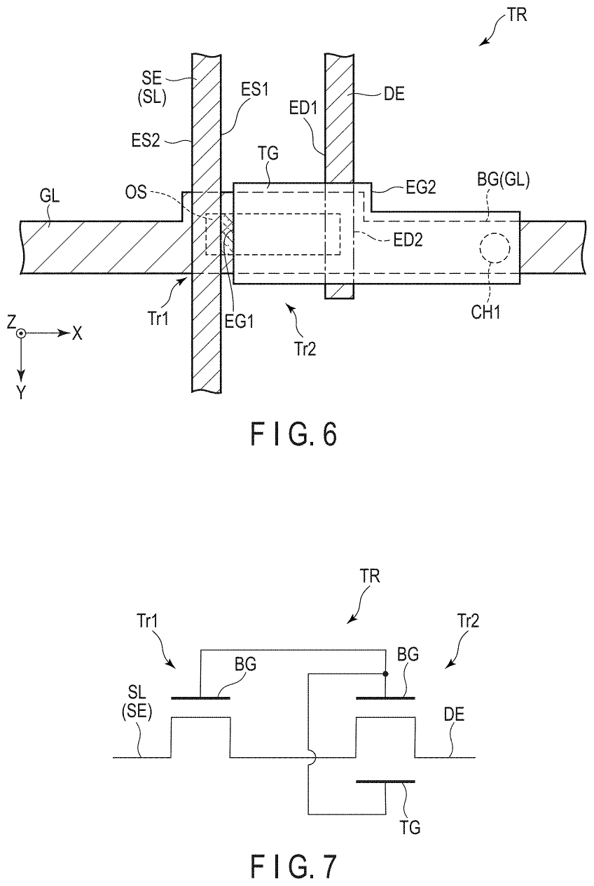

FIG. 6 is a plan view showing an example of a schematic configuration of a transistor including one oxide semiconductor layer. As shown in FIG. 6, since there is only one oxide semiconductor layer OS, the area occupied by the transistor TR can be reduced.

FIG. 7 is a circuit diagram showing a schematic configuration of a transistor. It can be said that the transistor TR is a transistor in which a bottom-gate transistor Tr1 provided with only gate electrode BG and a dual-gate transistor Tr2, in which both gate electrodes BG and TG are provided, are connected in series.

The region occupied by the transistor Tr2 corresponds to the region where the gate electrode TG overlaps the gate electrode BG. The region occupied by the transistor Tr1 corresponds to the region where the gate electrode TG does not overlap the gate electrode BG.

The channel length of the transistor Tr2 is the distance between the edge portion EG1 and the edge portion ED1. The channel length of transistor Tr1 is the distance between the edge portion ES1 and the edge portion EG1.

In this embodiment, the occurrence of ESD errors in the transistor TR can be suppressed, and the lowering of the aperture ratio of the display device DSP can be prevented. With this embodiment, it is possible to obtain a display device DSP with an improved yield rate, which has sufficient brightness.

### Embodiment 2

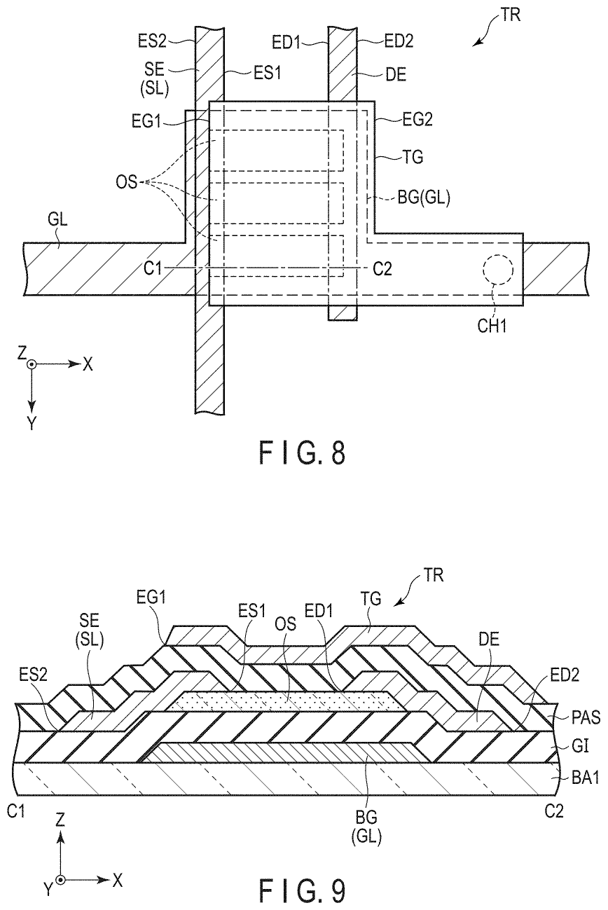

FIG. 8 is a plan view of another configuration example of a transistor in another embodiment. The configuration example shown in FIG. 8 is different from that of FIG. 4 in that the gate electrode TG overlaps a part of the signal line SL.

FIG. 8 is a plan view of an example of a schematic configuration of the transistor according to the embodiment. FIG. 9 is a cross-sectional view of the transistor taken along line C1-C2 shown in FIG. 8.

As explained with reference to FIG. 6, the transistor TR is a transistor in which a bottom-gate transistor Tr1 and a dual-gate transistor Tr2 are connected in series. When the distance between the edge portion ES1 and the edge portion EG1, which is the channel length of transistor Tr1, increases, the on-current of the transistor Tr1 may undesirably decrease.

The distance between the edge portion ES1 and the edge portion EG1 may undesirably vary from one to another among the plurality of transistors TR due to misalignment during the manufacturing process. Such non-uniformity in channel length may undesirably degrade the display quality of the display device DSP.

In the transistor TR of this embodiment, the gate electrode TG overlaps a part of the signal line SL (source electrode SE) but does not overlap any other part. In the transistor TR, the transistor Tr1 is not formed and only the transistor Tr2 is formed. In this manner, it is possible to suppress the occurrence of uneven channel length and the display quality of the display device DSP can be improved.

Here, the direction that intersects the extending direction of the signal line SL is referred to as the width direction. In FIG. 8, the second direction Y is the extending direction and the first direction X is the width direction.

The gate electrode TG overlaps the signal line SL along the width direction up to about half the length of the width thereof. However, it is does not overlap the other half of the length of the width of the signal line SL. Note here that the length of the width where the gate electrode TG overlaps the signal line SL is not limited to this. It suffices if the length of the overlapping width is determined so that the edge portion EG1 of the gate electrode TG is located on an inner side of the edge portion ES2 of the signal line SL.

The edge portion EG1 of the gate electrode TG is disposed between the edge portion ES1 and the edge portion ES2 of the signal line SL. The edge portion ES1 is disposed between the edge portion EG1 and the edge portion ED1 of the drain electrode DE. The edge portion ED1 and the edge portion ED2 of the drain electrode DE are disposed between the edge portion EG1 and the edge portion EG2 of the gate electrode TG.

In the manufacturing process of the insulating layer PAS, the film thickness may undesirably become less in the area near the edge portion ES1 and the edge portion ES2. If the film thickness is less, ESD errors may undesirably occur. In other words, the occurrence rate of ESD errors is high in the vicinities of the edge portion ES1 and the edge portion ES2.

The edge portion ES2 is placed not to overlap the gate electrode TG. With this configuration, the ESD errors can be suppressed on the edge portion ES2 side even if the film thickness of the insulating layer PAS becomes less.

On the other hand, the edge portion ES1 is placed to overlap the gate electrode TG. With this configuration, it is possible to prevent the formation of the transistor Tr1 and thus prevent variation in channel length.

In this embodiment, the gate electrode TG does not completely cover the signal line SL (source electrode SE), and therefore the aperture ratio is higher than that of the comparative example. In this embodiment, it is possible to suppress the occurrence of ESD errors while suppressing the decrease in the aperture ratio. Thus, it is possible to improve the display quality of the display device DSP.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first gate electrode formed to be integrated with a scanning line;
an oxide semiconductor layer;
a first signal line and a second signal line in contact with the oxide semiconductor layer; and
a second gate electrode disposed opposing the first gate electrode with the oxide semiconductor layer interposed therebetween, and connected to the first gate electrode, wherein
the second gate electrode does not overlap the first signal line, but overlaps the second signal line.

2. The semiconductor device according to claim 1, wherein
the first signal line includes a first edge portion and a second edge portion parallel to each other,
the second signal line includes a third edge portion and a fourth edge portion disposed parallel to the first edge portion and the second edge portion and parallel to each other,
the second gate electrode includes a fifth edge portion and a sixth edge portion disposed parallel to the first edge portion, the second edge portion, the third edge portion and the fourth edge portion and parallel to each other,
the first edge portion and the third edge portion are adjacent to and opposing each other,
the fifth edge portion is located between the first edge portion and the third edge portion, and
the third edge portion and the fourth edge portion are provided between the fifth edge portion and the sixth edge portion.

3. The semiconductor device according to claim 1, wherein the oxide semiconductor layer comprises a plurality of oxide semiconductor layers.

4. The semiconductor device according to claim 1, wherein the oxide semiconductor layer comprises a single oxide semiconductor layer.

5. A display device comprising:
a pixel provided at an intersection between the first signal line and the scanning line; and
a semiconductor device according to claim 1, provided in the pixel.

6. A semiconductor device comprising:
a first gate electrode formed to be integrated with a scanning line;
an oxide semiconductor layer;
a first signal line and a second signal line in contact with the oxide semiconductor layer; and
a second gate electrode disposed to oppose the first gate electrode with the oxide semiconductor layer interposed therebetween, and connected to the first gate electrode, wherein
the second gate electrode overlaps a part of the first signal line in a width direction of the first signal line and does not overlap any other part of the first signal line, and
the second gate electrode overlaps the second signal line.

7. The semiconductor device according to claim 6, wherein
the first signal line includes a first edge portion and a second edge portion parallel to each other,
the second signal line includes a third edge portion and a fourth edge portion disposed parallel to the first edge portion and the second edge portion and parallel to each other,
the second gate electrode includes a fifth edge portion and a sixth edge portion disposed parallel to the first edge portion, the second edge portion, the third edge portion and the fourth edge portion and parallel to each other,
the first edge portion and the third edge portion are adjacent to and opposing each other,
the fifth edge portion is located between the first edge portion and the third edge portion,
the first edge portion is provided between the fifth edge portion and the third edge portion, and
the third edge portion and the fourth edge portion are provided between the fifth edge portion and the sixth edge portion.

8. The semiconductor device according to claim 6, wherein the oxide semiconductor layer comprises a plurality of oxide semiconductor layers.

9. The semiconductor device according to claim 6, wherein the oxide semiconductor layer comprises a single oxide semiconductor layer.

10. A display device comprising:
a pixel provided at an intersection between the first signal line and the scanning line; and
a semiconductor device according to claim 6, provided in the pixel.
